(19) United States
(12) Patent Application Publication
(10) Pub. No.: US 2015/0228873 A1
(43) Pub. Date: Aug. 13, 2015

(54) Housing for an Optical Component, Assembly, Method for Producing a Housing and Method for Producing an Assembly

(71) Applicant: OSRAM Opto Semiconductors GmbH, Regensburg (DE)

(72) Inventors: Tobias Gebuhr, Regensburg (DE); Matthias Knörr, Tanjung Tokong Pulau Pinang (MY); Klaus Müller, Pettendorf (DE); Thomas Schwarz, Regensburg (DE); Frank Singer, Regenstauf (DE); Michael Zitzlsperger, Regensburg (DE)

(21) Appl. No.: 14/426,072

(22) PCT Filed: Aug. 28, 2013
(86) PCT No.: PCT/EP2013/067813

§ 371 Date: Mar. 4, 2015

(30) Foreign Application Priority Data
Sep. 5, 2012 (DE) 10 2012 215 705.0

(51) Int. Cl. H01L 33/62; H01L 21/56; H01L 21/48; H01L 51/56; H01L 51/52

(52) U.S. Cl. CPC H01L 33/62; H01L 51/56; H01L 51/5246; H01L 51/5296; H01L 21/4828; H01L 21/565; H01L 2933/0033; H01L 2933/0066

(57) ABSTRACT

A housing for an optical component is provided in various embodiments. The housing has a leadframe section and a mold compound. The leadframe section is formed from an electrically conductive material and has a first side and a second side facing away from the first side. On the first side, the leadframe section has at least one first receiving region for receiving the optical component and/or at least one contact region for electrically contacting the optical component. The leadframe section has at least one trench which is formed in the leadframe section on the first side thereof alongside the receiving region and/or the contact region. The leadframe section is embedded in the mold compound. The mold compound has at least one receiving recess in which the first receiving region and/or the contact region and the trench are arranged.

This patent application is a national phase filing under section 371 of PCT/EP2013/067813, filed Aug. 28, 2013, which claims the priority of German patent application 10 2012 215 705.0, filed Sep. 5, 2012, each of which is incorporated herein by reference in its entirety.

### TECHNICAL FIELD

The present invention relates to a housing for an optical component, an assembly, a method for producing a housing, and a method for producing an assembly.

### BACKGROUND

Known housings for optical components, e.g., for active and/or electronic optical components, e.g., quad-flat-no-leads (QFN) housings, comprise, e.g., leadframe sections as a base material. The QFN housings are also referred to as QFN packages and/or as micro leadframes (MLF) and are known in the field of electronics as chip-housing designs for integrated circuits (IC). In the present description, the term “QFN” comprises various sizes of IC housings which may all be soldered to printed circuit boards as surface-mounted components.

### SUMMARY

The present invention relates to a housing for an optical component comprising a leadframe section and a mold compound. The leadframe section is formed from an electrically conductive material. The leadframe section comprises a first side and a second side facing away from the first side. At the first side, the leadframe section comprises at least one first receiving region for receiving the optical component and/or at least one contact region for electrically contacting the optical component. The leadframe section is embedded in the mold compound. The mold compound comprises at least one receiving recess in which the first receiving region and/or the contact region are uncovered. Furthermore, the present invention relates to an assembly, to a method for producing a housing for an optical component and to a method for producing an assembly.

In the present description, the term “QFN” is used as a representative for the following terms: MLPQ (Micro Leadframe Package Quad), MLPM (Micro Leadframe Package Micro), MLPD (Micro Leadframe Package Dual), DRMLF (Dual Row Micro Leadframe Package), DFN (Dual Flat No-lead Package), TDFN (Thin Dual Flat No-lead Package), UTDFN (Ultra Thin Dual Flat No-lead Package), XDFN (eXtreme thin Dual Flat No-lead Package), QFN-TEP (Quad Flat No-lead package with Top Exposed Pad), TQFN (Thin Quad Flat No-lead Package), VQFN (Very Thin Quad Flat No Leads Package). As an essential material and contrary to the similar quad flat package (QFP), the electrical contacts (pins) do not laterally overlap the dimensions of the plastic coating, but are in a planar manner integrated into the bottom side of the housing in the form of non-tinned copper contacts. Thereby, the required space on the printed circuit board may be reduced and a higher package density may be achieved.

The leadframe sections are singularized from leadframes. The leadframes, e.g., comprise an electrically conductive material or are formed therefrom. The electrically conductive material, e.g., comprises a metal such as copper, e.g., CuW or CuMo, copper alloys, brass, nickel and/or iron, e.g., FeNi, and/or is formed therefrom.

The leadframe sections, e.g., serve to mechanically fix and/or electrically contact optical components, e.g., active or passive optical components. For this purpose, the leadframe sections, e.g., comprise receiving regions for receiving the optical components and/or contact regions for electrically contacting the optical components. The optical components may, e.g., be active optical components such as chips, e.g., semiconductor chips, and/or components emitting electromagnetic radiation, or passive optical components such as lenses, mirrors, screens or the like.

When producing the housings, the leadframes are embedded in a mold compound, e.g., during a molding process such as injection or transfer molding. The mold compound may be formed as a plastic coating. The structure consisting of mold compound and the leadframe embedded therein may also be referred to as a housing assembly. The fact that the leadframes or, respectively, leadframe sections are embedded in the mold compound, e.g., means that the leadframes or, respectively, leadframe sections are at least partly surrounded by the mold compound. Parts of the leadframes may remain free of mold compound, e.g., the electrical contacts for contacting the housings, particularly the leadframe sections of the housings, at the bottom side of the leadframes and/or the receiving recesses at the top surface of the leadframes in which the receiving regions and/or the contact regions are uncovered. In the receiving recesses, optical components may be arranged. Furthermore, the optical components arranged in the receiving recesses may be embedded in an encapsulation material. The electrical contacts of the housings are formed at a side of the leadframe sections opposite to the receiving recesses so that the finished housings may be mounted onto a printed circuit board. Via the resulting physical contact between the housing and the leadframe, the electrical contact to the leadframe section and/or to the optical component arranged thereon may be established.

When embedding the leadframes, mold compound may penetrate in areas which are supposed to remain free of mold compound, e.g., the receiving region and/or the contact region, e.g., due to a capillary effect between the leadframe and the corresponding mold compound. Said undesired penetration of mold compound is also referred to as “flash” or “EMC flash” (EMC=Electronic Mold Compound). The undesired mold compound must in the following be removed entirely or at least partially.

In known assemblies, a distance, e.g., between two optical components arranged in a housing is provided in such a way that a connecting material for connecting the optical components to the corresponding leadframe section during manufacturing may penetrate into the free space formed by the distance without resulting in a mutual influencing of the optical components and/or without influencing their positioning or orientation. For example, if the optical components comprise electronic components, an undesired conductive connection between the electronic components or a short may be generated via the excessive connecting material. If solder is used as a connecting material, the penetration of solder from the region between the optical component and the leadframe section is also known as “solder-squeeze-out”.

Furthermore, it may occur during manufacturing that the optical components are at first precisely arranged on the receiving region provided for this purpose and on the corresponding connecting material, however, the optical components may, in a plane parallel to the leadframe section, twist relative to the corresponding leadframe section and/or relative with regard to each other during liquefaction of the connecting material and/or during hardening of the connecting material. For example, this may occur if solder paste is used as a connecting material.

In various embodiment examples, a housing for an optical component and/or an assembly is provided which may be easily and/or precisely produced and/or in which one, two or more optical components may be arranged easily and/or precisely.

In various embodiment examples, a method for producing a housing for an optical component and/or a method for producing an assembly is provided which allows for producing the housing or, respectively, the assembly in a precise and simple manner and/or to precisely arrange one, two or more optical components in the housing or, respectively, in the assembly.

In various embodiment examples, a housing for an optical component is provided. The housing comprises a leadframe section and a mold compound. The leadframe section is formed from an electrically conductive material and comprises a first side and a second side facing away from the first side. On the first side of the leadframe section, the leadframe section comprises at least one first receiving region for receiving the optical component and/or at least one contact region for contacting the optical component. On the first side of the leadframe section beside the receiving region and/or beside the contact region, at least one trench is formed. The leadframe section is embedded in the mold compound and comprises at least one receiving recess. The first receiving region and/or the contact region and the trench are arranged in the receiving recess.

In the following, the trench is also referred to as fine trench and may be formed in such a way.

The trench may, e.g., contribute to prevent mold compound from penetrating into the contact region or the receiving region when embedding the leadframe section. In this context, the trench may, e.g., serve as a barrier to the mold compound. The trench may, e.g., hold mold compound which has flown into the trench, e.g., during manufacturing. The trench may, e.g., serve as a reservoir and/or as a stopping edge for the mold compound. A subsequent process for removing the mold compound from the receiving region and/or the contact region may be omitted.

Furthermore, the trench may serve to absorb superfluous connecting material during manufacturing which has, e.g., been arranged between an electronic component and the receiving region, in order to fix the optical component in the receiving region, and which in a liquid state is pressed beyond the receiving region. The trench may, e.g., hold connecting material which has flown into the trench during manufacturing. In other words, the trench may serve as a reservoir for superfluous connecting material. The receiving of superfluous connecting material in the fine trench may, e.g., allow for arranging two or more optical components closer to each other than would be possible without the fine trench.

Furthermore, the trench may, e.g., contribute to aligning one, two or more of the optical components on the leadframe section in a precise manner. For example, the fine trench may serve as an alignment marker for receiving and/or contacting the optical component.

The trench may, e.g., be formed between the mold compound and the first receiving region and/or between the mold compound and the contact region and/or between two receiving regions.

The housing is, e.g., formed as a QFN housing. This, e.g., means that the housing does not comprise wires leading outside which, e.g., protrude laterally from the housing and which would, e.g., have to be bent down when arranging the housing on a printed circuit board. Rather, the QFN housing comprises electrical contacts at its bottom side which are, e.g., formed by the leadframe section and by means of which, when mounting of the QFN housing onto the printed circuit board, a mechanical as well as electrical coupling of the QFN housing and, by means of the leadframe section, an electrical and/or thermal coupling of the optical component arranged therein to the printed circuit board is carried out. Moreover, the physical contact of the housing to the printed circuit board and the thermal coupling of the housing to the printed circuit board associated therewith may contribute to a very good behavior in case of alternating temperatures, as the material of the leadframe section may be particularly well adapted to the thermal expansion coefficient of the printed circuit board and/or of a heat sink. The printed circuit board may, e.g., be a FR1, FR2, FR3, FR4, FR5, CEM1, CEM2, CEM4, CEM4 or CEM5 printed circuit board, e.g., a FR-4 printed circuit board having a through-contact.

The optical components may, e.g., be active optical components such as chips, e.g., semiconductor chips, and/or components emitting electromagnetic radiation, or passive optical components such as lenses, mirrors, screens or the like.

In various embodiments, the trench (e.g., the fine trench) has a depth smaller than half the thickness of the leadframe section or smaller than a third of the thickness of the leadframe section. The fine trench may, e.g., have a width smaller than a thickness of the leadframe section. Thus, the fine trench is not a recess and/or a structure which may be formed by means of a full etch or a half etch of the leadframe comprising the leadframe section, but a flat recess or, respectively, structure. Such full or, respectively, half etches are known for manufacturing the structures of the individual leadframe sections and thus of the leadframe from a leadframe blank.

In various embodiments, the trench is at least partially arranged around the first receiving region and/or the contact region. For example, the trench delimits the first receiving region and/or the contact region on the first side of the leadframe section. In other words, the receiving region or, respectively, the contact region may be defined by a circumferential trench. This may contribute to the effective absorption of superfluous connecting material during manufacturing and/or to the precise alignment of the optical component to be arranged in the corresponding receiving section with regard to the leadframe section and/or of the receiving section and/or of another optical component.

In various embodiments, at least a second receiving region is provided on the leadframe section and the trench delimits the first receiving region from the second receiving region. This may, e.g., contribute to arranging the two optical components to be arranged on the first and the second receiving region closely to each other and/or precisely with regard to each other and/or with regard to the leadframe section.

In various embodiments, the trench is at least partially filled with a filler material. The filler material is, e.g., formed in such a way that it is not wetted by the used connecting material in either a liquid or, respectively, viscous state. This may, e.g., contribute to the precise alignment of the optical components. Generally, the wetting is a behavior of liquids when coming into contact with the surface of solid bodies. Wettability is the pertaining property. Depending on the type of liquid, the surface material and its texture, e.g., with regard to roughness, the liquids wets the surface more or less strongly. The wettability depends upon the ratios of the surface tensions involved which, e.g., correlate with the contact angle via the Young equation and thus make it a measure for the wettability. The larger the contact angle is in this context, the lower the wettability will be. Specifically, the surface tensions between the connecting material and the receiving region, the filler material and/or the optical component hereby play a major role.

In various embodiments an assembly is provided. The assembly comprises a housing, e.g., the above-described housing. Furthermore, the assembly comprises at least a first optical component arranged in the first receiving region of the housing and/or electrically contacted in the contact region of the housing. The optical component is, e.g., an active optical component such as a chip, e.g., a semiconductor chip, and/or a component emitting electromagnetic radiation, such as an LED or an OLED, or a passive optical component such as a lens, mirror or screen. By means of the fine trench, the optical component may be arranged and/or positioned and/or contacted on the housing and/or in the housing in a simple and particularly precise manner. Furthermore, two or more of the optical components may be arranged closely and thus densely with regard to each other by means of the fine trench.

In various embodiments, the first optical component at least partially overlaps the fine trench. In other words, e.g., in a top view onto the leadframe section the optical component may cover a part of the trench. In case the trench surrounds the first receiving region, the optical component may cover a larger area than the receiving region, wherein the optical component may overlap the receiving region, e.g., at one, two, three or at all sides. This may contribute to the precise arrangement and/or alignment of the optical component on the leadframe section and the receiving region. For example, an outer rim of the fine trench may surround a larger area than that of the bottom surface of the optical component. Thus, in a top view, only the outer rim of the trench and a part of the trench may be recognizable. In case the trench is filled with filler material, the connecting material cannot penetrate into the trench or to its filler material as it does not wet the filler material. Due to surface tensions between the connecting material and the bottom surface of the optical component, the filler material, the receiving region and the air, an automatic centering and/or alignment of the optical component is carried out via the receiving region. Thus, in other words, a precise and/or automatic positioning and orientation of the optical component may be achieved by means of the trench. Moreover, during embedding of the leadframe section, the trench may prevent liquid mold compound from penetrating into the receiving region and/or the contact region, thus allowing for arranging and/or contacting the optical component in a simple and/or precise manner.

In various embodiment examples, a method for producing a housing for an optical component is provided. In the method, a leadframe section is at first provided which is formed from an electrically conductive material and which comprises a first side and a second side facing away from the first side. At the first side, the leadframe section comprises a receiving region for receiving the optical component and/or a contact region for contacting the optical component. A trench is formed in the leadframe section on the first side adjacent to the receiving region and/or adjacent to the contact region. The leadframe section is embedded into the mold compound in such a way that the first receiving region and/or the contact region and the trench remain uncovered in the receiving recess.

In various embodiments, the trench is formed in such a way that the depth of the fine trench is smaller than half the thickness of the leadframe section or smaller than a third of the leadframe section. Alternatively or additionally, the trench is, e.g., formed in such a way that a width of the trench is smaller than the thickness of the leadframe section.

In various embodiment examples, the trench is at least partially formed around the first receiving region and/or the contact region. For example, the first receiving region and/or the contact region is delimited and/or defined on the first side of the leadframe by means of the trench.

In various embodiments, the leadframe section comprises at least a second receiving region for receiving a further optical component on the first side and the first receiving region is delimited from the second receiving region by the trench.

In various embodiments, the trench is at least partially filled with filler material, e.g., with the above-described filler material.

In various embodiments, a method for producing an assembly is provided. In this method, a housing for an optical component is at first provided, e.g., according to the above-described method. A melt binder is deposited in the first receiving region. At least one optical component, e.g., the above-described optical component, is arranged on the connecting material in the first receiving region and/or an electrical contact of the optical component is brought into contact with the connecting material in the contact region. The connecting material is molten and/or hardened, thus fixing the optical component in the first receiving region and/or electrically contacting the electrical contact of the optical component to the contact region. The electrical contact of the optical component may, e.g., comprise a wire, e.g., a bond wire.

In various embodiments, the trench is formed around the first receiving region and filled with the filler material and the optical component overlaps the trench. When melting the connecting material, the optical component is automatically aligned relative to the receiving region.

In various embodiments, the trench is formed around the second receiving region and filled with the filler material. The connecting material is arranged on the second receiving region. A further optical component is arranged on the connecting material in the second receiving region and overlaps the trench. The two optical components on the connecting material in the first and second receiving region are automatically aligned relative to the corresponding receiving regions and by means of the leadframe section.

### BRIEF DESCRIPTION OF THE DRAWINGS

Embodiment examples of the present invention are depicted in the drawings and explained in detail in the following. In the drawings,

FIG. 1 shows a top view onto elements of an embodiment example of an assembly;

FIG. 2 depicts a sectional view of the assembly of FIG. 1;

FIG. 3 is a top view onto elements of an embodiment example of an assembly;

FIG. 4 shows a sectional view of an assembly of FIG. 3;

FIG. 5 shows a sectional view of an embodiment example of an assembly;

FIG. 6 depicts a top view onto elements of an embodiment example of an assembly;

FIG. 7 shows a sectional view of the assembly of FIG. 6;

FIG. 8 is a top view onto elements of an embodiment example of an assembly;

FIG. 9 shows a sectional view of the assembly of FIG. 8;

FIG. 10 is a sectional view of the elements of an embodiment example of an assembly during manufacturing;

FIG. 11 shows a sectional view of the assembly of FIG. 10 during manufacturing;

FIG. 12 depicts a sectional view of an assembly of FIGS. 10 and 11 during manufacturing;

FIG. 13 is a sectional view of an embodiment example of an assembly;

FIG. 14 is a sectional view of an embodiment example of an assembly; and

FIG. 15 shows a flow chart of an embodiment example of a method for producing an assembly.

### DETAILED DESCRIPTION OF ILLUSTRATIVE EMBODIMENTS

In the following detailed description, reference is made to the accompanying drawings which are part of this description and in which, for the purpose of illustration, specific embodiment examples in which the invention may be realized are shown. In this context, directional terminology such as “top”, “bottom”, “front”, “back” etc. is used with reference to the orientation of the described drawing(s). As components of embodiment examples may be aligned in a number of different orientations, the directional terminology serves the purpose of clarity and is by no means limiting. Of course, different embodiment examples may be used and structural or logical modifications may be carried out without exceeding the protective scope of the present invention. Of course, the features of the embodiment examples described herein may be combined with one another if no specification to the contrary is given. The following detailed description is thus not to be considered limiting, and the protective scope of the present invention is defined by the appended claims.

Within the framework of the present invention, terms such as “connected”, “contacted” and “coupled” are used to describe a direct as well as indirect connection, a direct or indirect contact or a direct or indirect coupling. In the drawings, identical or similar elements are provided with identical reference numeral, if suitable.

An optical component may, e.g., be an active optical component such as a chip, e.g., a semiconductor chip, and/or a component emitting electromagnetic radiation, or a passive optical component such as a lens, a mirror, a screen or the like.

In various embodiment examples, a component emitting electromagnetic radiation may be a semiconductor component emitting electromagnetic radiation and/or a diode emitting electromagnetic radiation or a diode emitting organic electromagnetic radiation, a transistor emitting electromagnetic radiation or a transistor emitting organic electromagnetic radiation. The radiation may, e.g., be light in the visible range, ultraviolet light and/or infrared light. In this context, the component emitting electromagnetic radiation may, e.g., be formed as a light-emitting diode (LED), as an organic-light-emitting diode (OLED), as a light-emitting transistor or as an organic-light-emitting transistor. In various embodiment examples, the light-emitting component may be part of an integrated circuit. Moreover, a plurality of light-emitting components may be provided which is, e.g., accommodated in a shared housing.

In various embodiment examples, a connecting material may be a material for establishing a material-fit connection of two bodies, e.g., of an optical component having a carrier, e.g., a leadframe section. The connecting material may, e.g., be a material which is hard at room temperature and which is liquefied and hardened again in order to connect the bodies. In this context, the connecting material may be brought into contact with the two bodies already prior to liquefaction or not until it has acquired a liquid state. The connecting material may, e.g., be liquefied in an electric convector or in a reflow oven. As an alternative, the connecting material may, e.g., be a material which is liquid or at least viscous at room temperature, e.g., a glue, an adhesive paste or a soldering paste, e.g., a copper paste. The glue, the adhesive paste or, respectively, the soldering paste may, e.g., be hardened in an oven, e.g., in a reflow oven or in a steam oven. The connecting material may, e.g., comprise a plastic material such as a synthetic resin and/or a metal such as solder. The solder may, e.g., comprise an alloy. The solder may, e.g., comprise lead, tin, zinc, copper, silver, aluminum, silicon and/or glass and/or organic or inorganic additives.

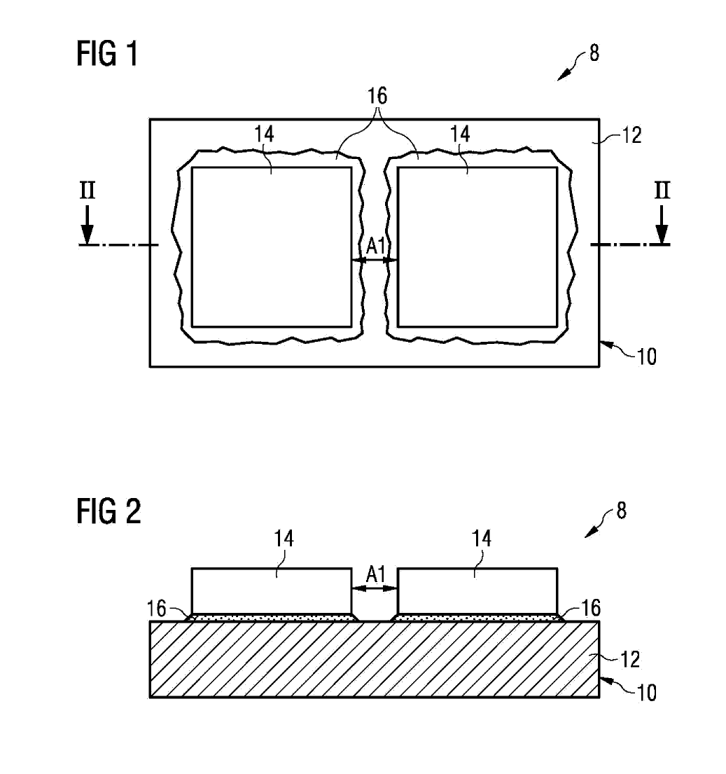

FIG. 1 and FIG. 2 show elements of a conventional assembly. FIG. 1 shows a top view onto the elements of the conventional assembly 8 and FIG. 2 shows a sectional view of the conventional assembly 8 shown in FIG. 1. The conventional assembly 8 shows two optical components 14 and a housing 10 in which the optical components 14 are arranged. FIG. 1 and FIG. 2 show only a part of the housing 10. The housing 10 inter alia comprises a leadframe section 12. The leadframe section 12 comprises a receiving region for each of the optical components 14 at a first side of the leadframe section 12. On the leadframe section, the two optical components 14 have been fixed in the receiving regions by means of a connecting material 16.

The two optical components 14 are arranged relative to each other at a first distance in such a way that the connecting material 16 may, in a liquid or viscous state, at least partially protrude from under the optical components during manufacturing, without the connecting materials 16 influencing and/or coming into contact with each other and/or with the optical component 14 in the two receiving regions. The first distance A1 may, e.g., be a minimum distance to be observed and/or may amount to 0.1 mm to 10 mm. The minimum distance may, e.g., contribute to prevent an undesired electrical coupling of the two optical components 14 and/or a short between the two optical components 14.

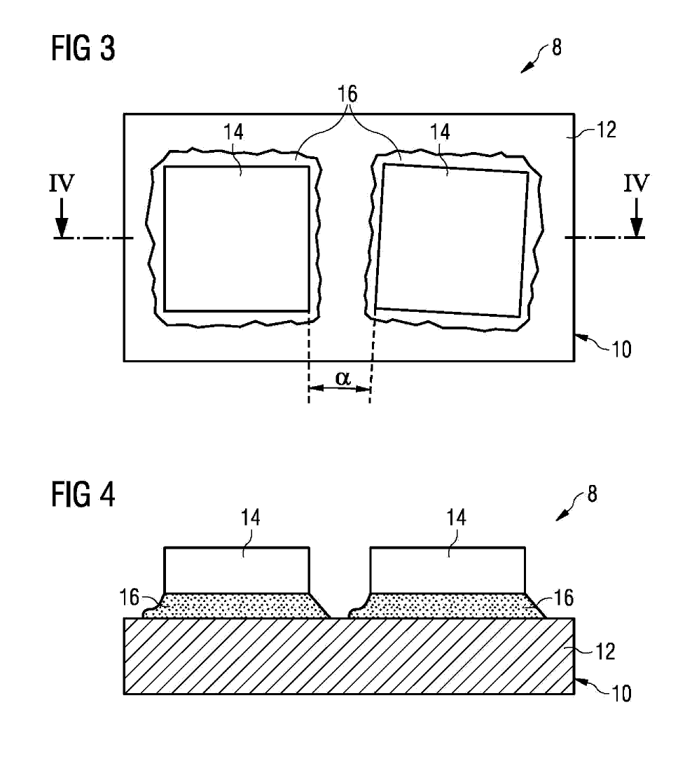

FIG. 3 and FIG. 4 show elements of a conventional assembly which may, e.g., largely correspond to the above-described elements of the conventional assembly 8. FIG. 3 shows a top view onto the elements of the conventional assembly 8 and FIG. 4 shows a sectional view of assembly 8 of FIG. 3. For example, the two optical components may be arranged on the leadframe section 12 in such a way that their lateral edges facing each other include a first angle α. The two optical components 14 may, e.g., include the first angle α even if they were precisely arranged in parallel with regard to each other prior to fixing them to the receiving region of the leadframe section 12, because, e.g., during liquefaction of the connecting material 16 and/or prior to or upon hardening the connecting material 16, a twist of the optical components 14 relative to one another and/or relative to the leadframe section 12 may occur.

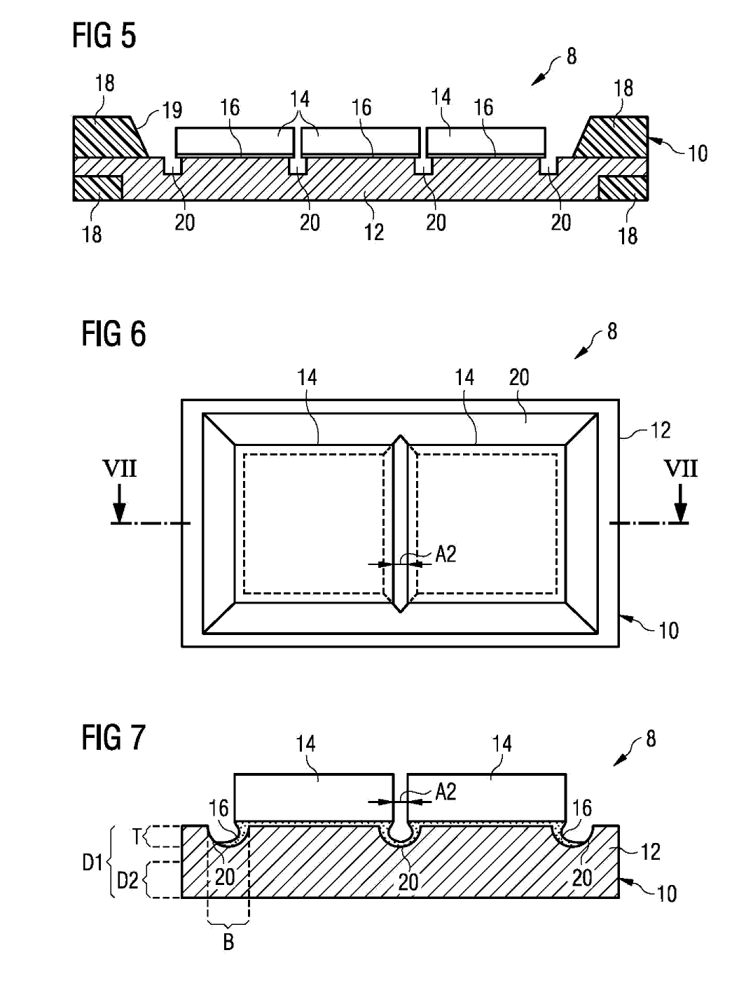

FIG. 5 shows a sectional view through an embodiment example of an assembly 8 in which the leadframe section 12, the optical components 14 and/or the connecting material 16 may, e.g., be formed largely in accordance with the above-described elements of the conventional assembly 8. For example, the leadframe section 12 comprises one, two or more, e.g., three receiving regions for receiving corresponding optical components 14. By means of the connecting material 16, the optical components 14 are arranged and/or fixed on the receiving regions. Moreover, the leadframe section 12 may comprise one, two or more contact regions (cf. FIG. 14) by means of which the optical components 14 may be electrically contacted. The connecting material 16 may, e.g., comprise a thin-film soldering layer.

Moreover, the assembly 8 may, e.g., comprise a mold compound 18 in which the leadframe section 12 may be embedded. The fact that the leadframe section 12 may be embedded in the mold compound may, e.g., mean that the leadframe section 12 is at least partially surrounded by the mold compound 18; however, the leadframe section 12 may be free of mold compound 18 in individual areas. For example, the leadframe section 12 in FIG. 5 may be free of mold compound 18 over a larger area at its bottom surface. The leadframe section 12 and/or the optical components 14 may, e.g., be electrically and/or thermally contacted, e.g., via the bottom surface, e.g., with a printed circuit board (not shown). Moreover, the leadframe section 12 may comprise a receiving recess 19 at its top surface shown in FIG. 5, wherein the receiving recess 19 may be free of mold compound 18 and in which the receiving regions and, if the case may be, the contact regions are uncovered.

Adjacent to the receiving regions and/or, if the case may be, adjacent to the contact regions, one, two or more trenches 20, e.g., two or more fine trenches 20, may be formed in the receiving recess 19. For example, trenches 20, e.g., fine trenches 20, may be formed between the receiving regions and the mold compound 18 and/or between the individual receiving regions. The fine trenches may, e.g., be completely or partially formed around the receiving regions or, respectively, the contact regions. The fine trenches may, e.g., comprise a depth and a width which will be explained in more detail below with reference to FIG. 7.

The receiving regions may, e.g., be at least partially filled with connecting material 16 which flows forth between the receiving regions and the corresponding electronic elements 14, e.g., during manufacturing when the connecting material 16 is liquefied, and is received by the corresponding fine trenches 20. As a result, the optical components 14 may, e.g., be arranged more closely to each other than without fine trenches 20, e.g., closer than in the conventional assembly 8 shown in FIGS. 1 and 2. The fine trenches may thus, e.g., serve to absorb the liquid connecting material 16.

Alternatively or additionally, the fine trenches 20 formed between the receiving regions and the mold compound 18 and/or between the contact regions and the mold compound 18 may serve to absorb liquid mold compound 18 during embedding of the leadframe section so that the receiving regions or, respectively, the contact regions remain free of mold compound 18. Thus, the fine trenches 20 may serve as a barrier to the liquid mold compound 18 and/or as a reservoir for the liquid mold compound 18. This may contribute to be able to simply and/or precisely align the optical components 14 in the receiving regions and/or to be able to simply and/or precisely electrically contact the optical components 14 in the contact regions.

FIG. 6 shows elements of an embodiment example of an assembly 8 which may, e.g., largely correspond to the above-described elements of the assemblies 8. For example, the elements of the assembly 8 may be a combination of the above-described elements of the assemblies 8. For example, the leadframe sections 12 and the optical components 14 may be formed according to the FIGS. 1 to 4 and the fine trench 20 may be formed according to the embodiment example shown in FIG. 5. For example, the fine trench 20 may extend around the two optical components 14. The fine trench 20 may, e.g., be formed in such a way that it separates two receiving regions from each other on the first side of the leadframe section 12. The optical components 14 may, e.g., overlap the receiving regions, which is why in FIG. 6 the outer rims of the receiving regions which, e.g., correspond to the inner rims of the fine trench 20 are only shown as dashed lines. The fine trench 20 shown in FIG. 6 may be referred to as a circumferential fine trench 20 or as a plurality of fine trenches 20 formed adjacent to the receiving regions and/or between the receiving regions.

The two optical components 14 may, e.g., be arranged at a second distance A2 with regard to each other, the second distance A2 being, e.g., smaller than the first distance A1. The second distance A2 may, e.g., amount to only a few micrometers or even to zero. When manufacturing the assembly 8 and particularly when fixing the optical components 14 to the leadframe section 12, superfluous connecting material 16 may flow off via the fine trench 20.

FIG. 7 shows a sectional view of the assembly 8 of FIG. 6. The fine trenches 20 shown in FIG. 7 may, e.g., be formed in accordance with the above-described and/or the below-described fine trenches 20. The fine trenches 20 may, e.g., have a depth T which is, e.g., smaller than half a thickness D2 of the leadframe section 12. The leadframe section 12 may, e.g., have a thickness D1 of 350 μm. The depth T may, e.g., correspond to a third of the first thickness D1 or be smaller than the first thickness D1. A width of the fine trenches 20 may, e.g., correspond to the depth T of the fine trenches or correspond to 1.5 times, twice or three times the depth T of the fine trenches 20.

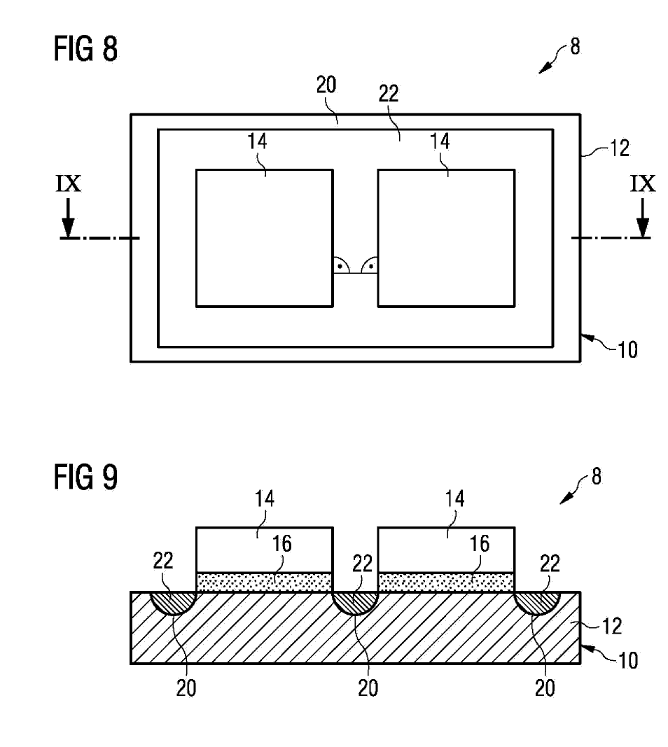

FIG. 8 and FIG. 9 show elements of an embodiment example of an assembly 8 which may, e.g., largely correspond to the above-described elements of assemblies 8. FIG. 8 shows a top view onto the elements of assembly 8 and FIG. 9 shows a sectional view of the assembly 8 of FIG. 8.

In the fine trench 20, e.g., a filler material 22 may be arranged. The filler material 22 may, e.g., be formed in such a way that it is not wetted by the connecting material 16. As a result, the liquid connecting material 16 does not flow into and/or onto the fine trench 20 or, respectively, the filler material 22 during manufacturing, but remains in the receiving region and/or the contact region. If the receiving region is precisely defined by the fine trench 20, the surface tensions between the connecting material 16 and the optical component 14, the leadframe section 12 and/or the surrounding air may result in an automatic alignment and/or precise positioning and/or precise orientation of the optical components 14 with regard to the leadframe section 12 and/or to the corresponding receiving region and/or with regard to each other. In other words, the optical components 14 on the connecting material 16 are automatically aligned or centered on the corresponding receiving regions. This allows for at first aligning the optical components 14 relatively imprecisely on the still solid connecting material 16, e.g., more imprecisely than in the conventional assembly 8 shown in FIGS. 3 and 4, and still achieving a relatively precise fixing of the optical components 14 to the leadframe section 12, e.g., a more precise fixing than in the conventional assembly 8 of FIGS. 3 and 4, after hardening of the connecting material 16. This may, e.g., be advantageous when using soldering paste as a connecting material 16 and/or during paste-soldering.

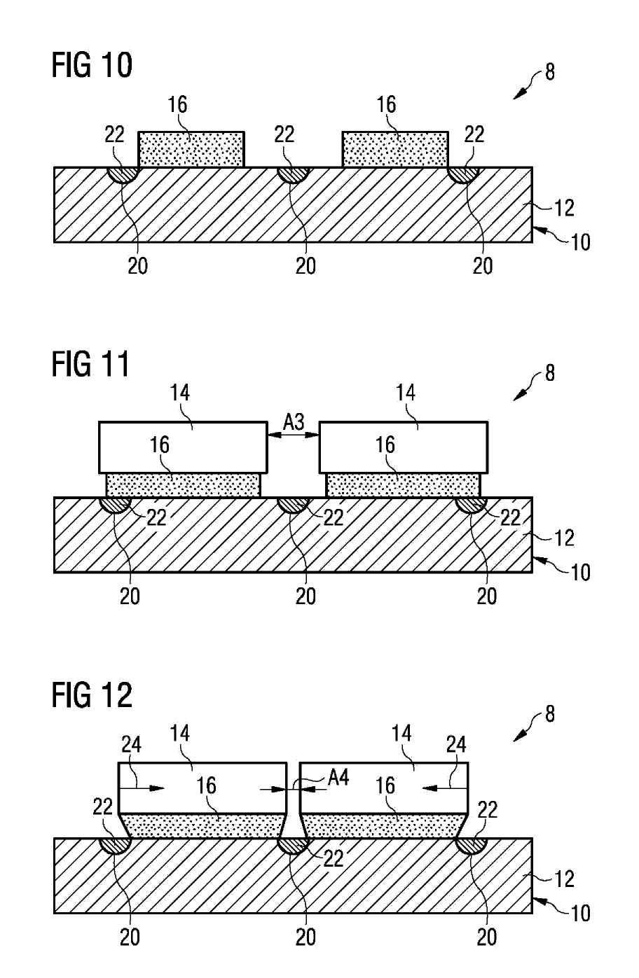

FIG. 10, FIG. 11 and FIG. 12 show exemplary states of an embodiment example of an assembly 8, in which the assembly 8 may be during manufacturing of the assembly 8. The various states particularly show how the optical components 14 may be arranged on the leadframe section 12. The assembly 8 may, e.g., largely correspond to the above-described assemblies 8.

FIG. 10 shows a state of the assembly 8 in which the fine trenches 20 of the leadframe section 12 are filled with filler material 22. As a filler material 22, a material is used which is not wetted by the connecting material 16. The connecting material 16 is arranged in the receiving regions. As the connecting material 16, e.g., a soldering paste may be used which may, e.g., be disposed on the leadframe section 12 by means of a printing process or by means of a dispensing process.

FIG. 11 shows a state of the assembly 8 of FIG. 10, in which the optical components 14 are arranged on the leadframe section 12 and the connecting material 16. The two optical components 14 have a third distance A3 with regard to each other. The connecting material 16 may, e.g., overlap a part of the fine trench 20 and/or of the filler material 22.

FIG. 12 shows a state of the assembly 8 of FIGS. 10 and 11, in which the connecting material retreats from the filler material 22 due to its material properties. On the one hand, this has the effect that the two optical components 14 move towards each other from opposite directions 24; as a result, the two optical components 14 have a fourth distance A4 with regard to each other which is smaller than the third distance A3. Moreover, a relative alignment of the optical components with regard to the leadframe section 12 and particularly with regard to the receiving regions and, via the leadframe section 12, also relative to each other is carried out. A difference between the third distance A3 and the fourth distance A4 may, e.g., be in the range between 10 μm and 30 μm, e.g., between 15 μm and 25 μm, e.g., around 20 μm.

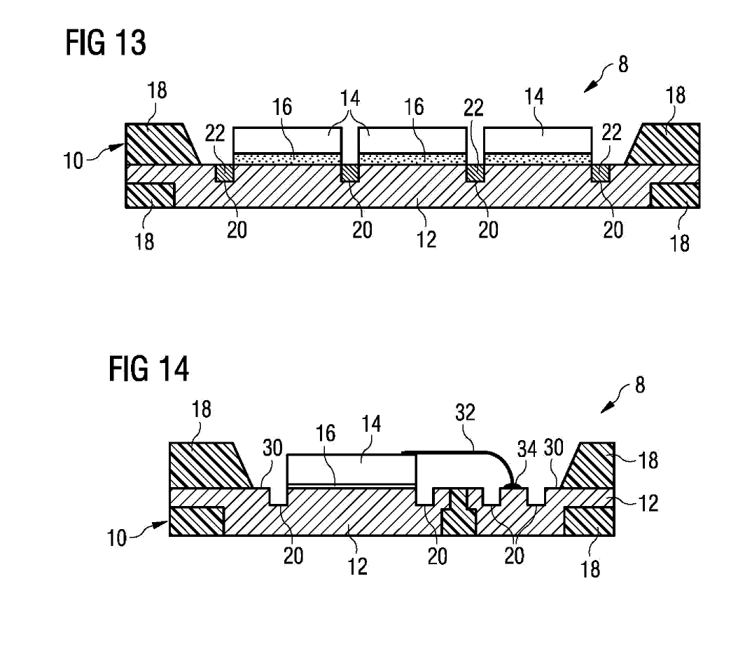

FIG. 13 shows an embodiment example of the assembly 8 which may largely correspond to the above-described embodiment examples of the assembly 8. The fine trenches 20 may, e.g., be filled with the filler material 22. The optical components 14 may, e.g., be arranged particularly closely to each other, and/or precisely with regard to each other and/or with regard to the housing 10. Moreover, further optical components 14 may be arranged in the housing 10 and/or be surrounded by further fine trenches 20. As the connecting material 16, e.g., a soldering paste may be used which is, e.g., deposited in a printing or dispensing process and/or subsequently hardened in a reflow oven.

FIG. 14 shows an embodiment example of assembly 8 which may largely correspond to the above-described embodiment examples of assembly 8. The assembly 8, e.g., comprises a leadframe section 12 which comprises a receiving section and a contact section. The receiving section comprises the receiving region on the first side of the leadframe section 12, the optical component 14 being fixed in the receiving region by means of the connecting material 16. The contact section comprises a contact region 34 which may, e.g., be formed in accordance with the above-described contact regions. The optical component may be electrically contacted with the contact region 34, e.g., by means of a bond wire 32. For example, the receiving region and/or the contact region 34 may be surrounded by fine trenches 20. For example, one fine trench 20 is formed between the receiving region and the mold compound 18 and/or between the contact region 34 and the mold compound 18, respectively.

Surface areas 30 of the leadframe section 12 are, e.g., formed between the mold compound 18 and the adjacent fine trenches 20, said surface areas 30 being covered with mold compound 18 (flash). Moreover, the fine trenches 20 adjacent to the mold compound 18 may hold some of the mold compound 18. For example, the mold compound 18 may penetrate into the surface areas 30 and the corresponding fine trenches 20 during embedding due to capillary forces. Due to the fine trenches 20, however, the receiving region and/or the contact region 34 remain free of mold compound 18 as the fine trenches 20 interrupt the capillary effect and serve as a reservoir for the liquid mold compound 18. In other words, the fine trenches 20 form stopping edges for the mold compound 18 (flash stop).

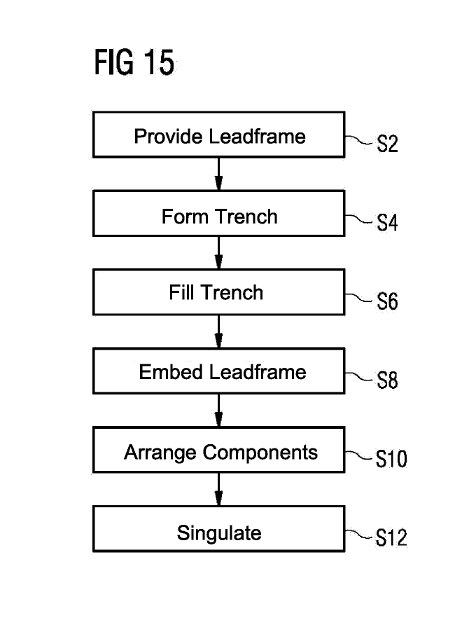

FIG. 15 shows a flow chart of an embodiment example for manufacturing an assembly 8. The method for manufacturing the assembly 8 also comprises the method for manufacturing the housing 10 for the assembly 8.

In a step S2, a leadframe is provided. The leadframe may, e.g., comprise a plurality of leadframe sections 12 which are connected via the leadframe and/or which in combination form the leadframe. The leadframe and/or the leadframe sections 12 may, e.g., formed from a leadframe blank by means of one or two etching processes.

In a step S4, a fine trench may be formed, e.g., one or several of the fine trenches 20 in the leadframe section 12. The fine trench 20 may, e.g., be formed in the same etching process as the leadframe sections. In other words, steps S2 and S4 may be carried out simultaneously. Alternatively, the fine trenches may also be formed in a proprietary etching process or by means of stamping, sawing and/or milling. In order to form one of the fine trenches 20, e.g., an etching mask and/or a photo-resin may be used which in the area of the fine trench 20 have a slit with a width of, e.g., 5 μm to 200 μm, e.g., between 10 μm and 50 μm.

In a step S6, the fine trenches 20 may be filled with filler material 22. The filler material 22 has, e.g., the property that it is not or only insignificantly wetted by the connecting material 16. As a filler material 22, e.g., the same material may be used as for the mold compound 18.

In a step S8 the leadframe may be embedded into the mold compound 18. If the mold compound 18 is used as a filler material 22, steps S6 and S8 may be carried out simultaneously. For example, the fine trenches 20 may be filled with the mold compound 18 when embedding the leadframe. The embedded leadframe forms a housing assembly which comprises a housing 10 for each leadframe section 12.

In a step S10, the optical components 14 may be arranged on the leadframe, particularly on the leadframe sections 12. The optical components 14 may be fixed to the leadframe sections 12, e.g., by means of the connecting material 16. The connecting material 16 may be deposited on the leadframe sections 12, e.g., by means of sputtering, dispensing, printing and/or vaporizing. The optical components 14 may, e.g., be arranged on the leadframe sections 12 by means of a thin-film-soldering process.

In a step S12, the assemblies 8 and/or the housings 10 may be singularized. The assemblies 8 or, respectively, the housings 10 may be singularized by means of sawing or cutting the housing assembly.

Step S10 may be carried out prior to or after step S12. If step S10 is carried out after step S12, the steps S2 to S12 may be referred to as method for manufacturing the housing 10.

The present invention is not limited to the indicated embodiment examples. For example, the fine trenches may be formed adjacent to all regions by means of mold compound 18 so that the mold compound 18 may in principle flow into the fine trench 20, and not beyond the fine trench 20. Moreover, differently formed receiving regions and/or differing numbers of receiving regions may be separated from each other or from the mold compound by means of the fine trenches 20. In addition, in all embodiment examples contact regions may be separated from each other, from the receiving regions or from the mold compound 18 by means of the fine trenches 20. Moreover, the shown embodiment examples may be combined with each other. Moreover, the shown embodiment examples may only comprise one optical component 14 and accordingly only one receiving region and/or more than three, e.g., four, five or more receiving regions and corresponding optical components 14. Moreover, in FIGS. 5 to 13 may comprise one, two or more contact regions 34 according to FIG. 14.

1-15. (canceled)

16. A housing for an optical component, the housing comprising:
a leadframe section formed from an electrically conductive material, the leadframe section comprising a first side and a second side facing away from the first side and, at the first side, a conductive region, the conductive region comprising a first receiving region for receiving the optical component or a contact region for electrically contacting the optical component;
a trench formed in the leadframe section on the first side adjacent to the conductive region; and
a mold compound embedded into the leadframe section and comprising a receiving recess in which the conductive region and the trench are arranged.

17. The housing of claim 16, wherein the trench has a depth smaller than half a first thickness of the leadframe section or smaller than a third of a second thickness of the leadframe section.

18. The housing of claim 16, wherein the trench has a width smaller than a thickness of the leadframe section.

19. The housing of claim 16, wherein the trench is at least partially formed around the conductive region.

20. The housing of claim 16, wherein the leadframe section comprises the first receiving region and a second receiving region and wherein the trench delimits the first receiving region from the second receiving region.

21. The housing of claim 16, wherein the trench is at least partially filled with a filler material.

22. The housing of claim 21, wherein the filler material is formed in such a way that it is not wetted by a connecting material.

23. An assembly comprising a housing according to claim 16 and the optical component arranged in the first receiving region of the housing and/or electrically contacted in the contact region of the housing.

24. The assembly of claim 23, wherein the optical component at least partially overlaps the trench.

25. A method for producing a component, the method comprising:
providing a leadframe section that is formed from an electrically conductive material, the leadframe section comprising a first side and a second side facing away from the first side and, at the first side, a conductive region that comprises a first receiving region for receiving an optical component or a contact region for electrically contacting the optical component;
forming a trench in the leadframe section on the first side adjacent to the conductive region; and
embedding the leadframe section in a mold compound in such a way that the conductive region and the trench are arranged in a receiving recess of the mold compound.

26. The method of claim 25, wherein the trench is formed in such a way that a depth of the trench is smaller than half a first thickness of the leadframe section or smaller than a third of a second thickness of the leadframe section.

27. The method of claim 25, wherein the trench is formed in such a way that a width of the trench is smaller than a thickness of the leadframe section.

28. The method of claim 25, wherein the trench is at least partially formed around the conductive region.

29. The method of claim 25, wherein the leadframe section on its first side comprises the first receiving region and a second receiving region for receiving a second optical component and wherein the first receiving region is delimited from the second receiving region by the trench.

30. The method of claim 25, wherein the trench further comprising at least partially filling with a filler material.

31. The method of claim 30, wherein the filler material is formed in such a way that it is not wetted by a connecting material.

32. The method of claim 25, further comprising:
depositing a connecting material over the conductive region;
arranging an optical component on the connecting material so that the optical component is brought into contact with the connecting material on the contact region; and
fixing the optical component on the connecting material and in electrical contact with the conductive region.

33. The method of claim 32, wherein fixing the optical component comprises melting and hardening the connecting material.

34. The method of claim 33, wherein the conductive region comprises the first receiving region, wherein the trench is formed around the first region and filled with a filler material, wherein the optical component overlaps the trench, and wherein during melting of the connecting material the optical component is automatically aligned relative to the receiving region.

35. The method of claim 34, wherein:
the conductive region comprises the first receiving region and a second receiving region;
the trench is formed around the second receiving region and filled with the filler material;
the connecting material is arranged over the second receiving region;
a further optical component is arranged on the connecting material in the second receiving region and overlaps the trench; and
the optical components and the further optical component are automatically aligned relative to the first and second receiving regions and relative with regard to each other on the connecting material in the first and second receiving regions.
